(19) United States
(12) Patent Application Publication
(10) Pub. No.: US 2026/0157125 A1
(43) Pub. Date: Jun. 4, 2026

(54) LASER-ASSISTED EPITAXY AND ETCHING FOR MANUFACTURING INTEGRATED CIRCUITS

(71) Applicant: Taiwan Semiconductor Manufacturing Co., Ltd., Hsinchu (TW)

(72) Inventors: Yee-Chia Yeo, Hsinchu (TW); Syun-Ming Jang, Hsinchu (TW); Wei-Jen Lo, Hsinchu (TW)

(21) Appl. No.: 19/458,043

(22) Filed: Jan. 23, 2026

Related U.S. Application Data
(63) Continuation of application No. 17/457,709, filed on Dec. 6, 2021.
(60) Provisional application No. 63/140,297, filed on Jan. 22, 2021.

(51) Int. Cl. H10P 14/20; C23C 16/04; C23C 16/48; C30B 25/10; H10P 50/00; H10P 95/90

(52) U.S. Cl. CPC H10P 14/38; C23C 16/047; C23C 16/483; C30B 25/105; H10P 14/20; H10P 50/00; H10P 95/90

(57) ABSTRACT

A method includes placing a wafer into a production chamber, providing a heating source to heat the wafer, and projecting a laser beam on the wafer using a laser projector. The method further includes, when the wafer is heated by both of the heating source and the laser beam, performing a process selected from an epitaxy process to grow a semiconductor layer on the wafer, and an etching process to etch the semiconductor layer.

### PRIORITY CLAIM AND CROSS-REFERENCE

This application is a continuation of U.S. patent application Ser. No. 17/457,709, entitled “LASER-ASSISTED EPITAXY AND ETCHING FOR MANUFACTURING INTEGRATED CIRCUITS,” and filed Dec. 6, 2021, which claims the benefit of the following provisionally filed U.S. Patent application: Application No. 63/140,297, filed on Jan. 22, 2021, and entitled “Laser-assisted epitaxy and etching for manufacturing of semiconductors,” which application is hereby incorporated herein by reference.

### BACKGROUND

The manufacturing of integrated circuits comprises multiple process steps, including epitaxy and etching of semiconductor regions. The epitaxy and etching processes are generally performed at wafer level, and the epitaxy and the etching are performed on an entire wafer. The wafer may include a plurality of chips therein, which are later sawed apart from each other. To maintain the yield of the manufacturing process, the uniformity of the epitaxy and the etching processes throughout the wafer needs to be maintained. While the epitaxy step and etching step may be each performed in separate process chambers or tools, they can also be performed in the same process chamber or tool. Multiple epitaxy and multiple etching steps can be performed sequentially in the same process chamber or tool.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates the cross-sectional view of a wafer in accordance with some embodiments.

FIGS. 2 and 3 illustrate the non-uniformity of epitaxy layers formed on wafers in accordance with some embodiments.

FIG. 4 illustrates an apparatus and an epitaxy/etching process performed on a wafer using laser-assisted heating in accordance with some embodiments.

FIG. 5 illustrates a top view of a wafer with laser beam spots on the wafer in accordance with some embodiments.

FIG. 6 illustrates an apparatus and an epitaxy/etching process performed on a wafer using laser-assisted heating in accordance with some embodiments.

FIG. 7 illustrates a top view of a wafer with laser beam spots on the wafer in accordance with some embodiments.

FIG. 8 illustrates an apparatus and an epitaxy/etching process performed on a wafer using laser-assisted heating in accordance with some embodiments.

FIG. 9 illustrates a top view of a wafer with laser beam spots on the wafer in accordance with some embodiments.

FIG. 10 illustrates an apparatus and an epitaxy/etching process performed on a wafer using laser-assisted heating in accordance with some embodiments.

FIG. 11 illustrates a top view of a wafer with laser beam spots on the wafer in accordance with some embodiments.

FIG. 12 illustrates the cross-sectional view of epitaxy semiconductor regions at different locations of a wafer in accordance with some embodiments.

FIG. 13 illustrates the etching of epitaxy semiconductor regions at different locations of a wafer in accordance with some embodiments.

FIG. 14 illustrates a process flow for determining process parameters of a laser-assisted heating process in accordance with some embodiments.

FIG. 15 illustrates a process flow for performing laser-assisted epitaxy and etching processes in accordance with some embodiments.

FIG. 16 illustrates a process flow for performing laser-assisted etching processes in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A laser-assisted epitaxy or etching process and the corresponding apparatus for performing the same are provided. In accordance with some embodiments of the present disclosure, an epitaxy or etching process is performed on a wafer using a lamp-based heating source. A laser beam is provided to selectively heat selected regions on the wafer. The laser beam may be fixed to heat certain points on the wafer, or may be movable (either slide on a track or have an adjustable projecting angle), so that the heated locations may be adjusted. Furthermore, the power of the laser beam may be adjusted, depending on the required heating at the selected locations. The spot size of the laser may also be adjusted by altering the focus of the laser on the wafer. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

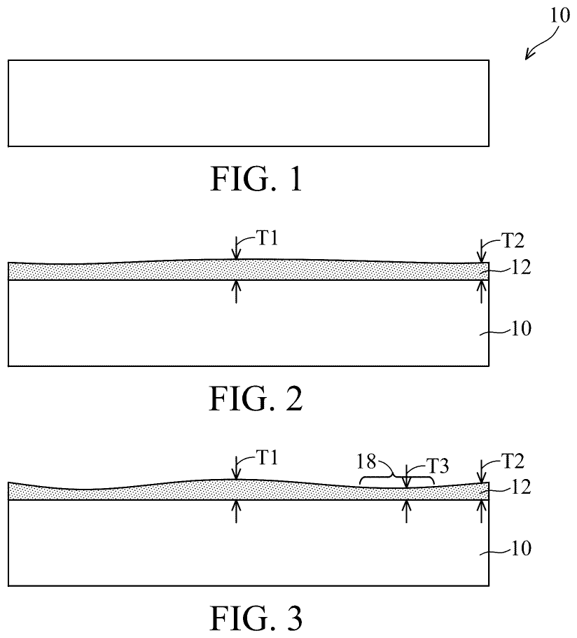

FIG. 1 illustrates a cross-section view of wafer 10. In accordance with some embodiments, wafer 10 includes a semiconductor substrate, which may comprise a silicon substrate, a silicon germanium substrate, a germanium substrate, or the like. Wafer 10 may include a plurality of different regions formed of different materials, which regions may include, and are not limited to, Shallow Trench Isolation (STI) regions, gate stacks, gate spacers, or the like. Wafer 10 may also comprise of a plurality of silicon germanium and silicon regions formed on a silicon substrate. The different regions in wafer 10 are not shown individually. In the wafer 10 as shown in FIG. 1, the surfaces of semiconductor regions and the surfaces of dielectric regions may be exposed. The exposed surfaces of dielectric regions may include, and are not limited to, the surfaces of STI regions, gate spacers, hard masks, fin spacers, Inter-layer Dielectric (ILD), or the like. The exposed dielectric materials of the dielectric regions may include, and are not limited to, silicon oxide, silicon nitride, silicon oxynitride, silicon oxy-carbo-nitride, aluminum oxide, aluminum nitride, or the like. The exposed semiconductor materials, on which epitaxy will occur, may include semiconductor fins, semiconductor strips, semiconductor substrates, or the like. The exposed semiconductor material may include, and are not limited to, silicon, silicon germanium, germanium, III-V semiconductors, or the like.

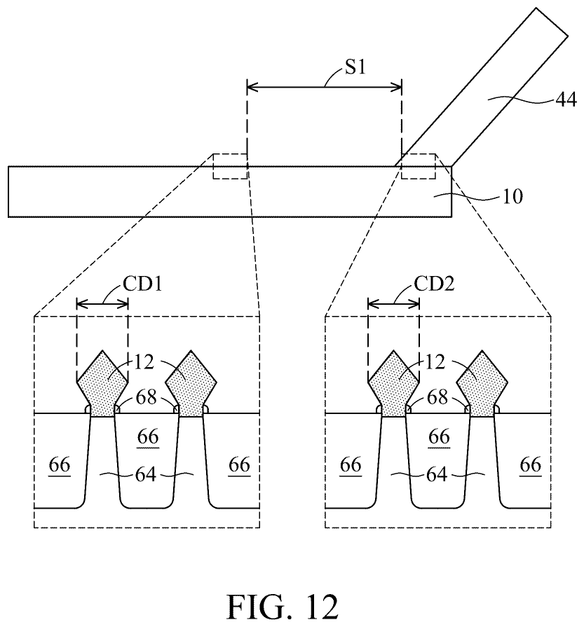

FIG. 2 schematically illustrates the epitaxy of semiconductor layer 12. Semiconductor layer 12 may be or may comprise silicon, germanium, silicon germanium, gallium arsenide (GaAs), indium gallium arsenide (InₓGa₁₋ₓAs), indium aluminium arsenide (InₓAl₁₋ₓAs), indium phosphide (InP), indium antimonide (InSb), indium gallium antimonide (InₓGa₁₋ₓSb), gallium antimonide (GaSb), or the like, or combinations thereof. In accordance with some embodiments, semiconductor layer 12 is epitaxially grown as a blanket layer, for example, when forming a fully strained silicon germanium layer or a fully strained germanium layer on a silicon substrate. In accordance with alternative embodiments, semiconductor layer 12 is epitaxially grown in selected regions, such as on the exposed semiconductor fins or semiconductor strip, but not on the exposed dielectric regions such as STI regions, gate spacers, fin spacers, hard masks, or the like. A selectively grown semiconductor layer is shown in FIG. 12 as an example. The epitaxial growth of semiconductor layer 12 in FIGS. 2 and 3 represents both of the blanket epitaxial growth and selective epitaxial growth.

In accordance with some embodiments, the epitaxial growth is performed using Chemical Vapor Deposition (CVD), Atomic Layer Deposition (ALD), Reduced Pressure Chemical Vapor Deposition (RPCVD), Plasma Enhanced Chemical Vapor Deposition (PECVD), or the like. In accordance with some embodiments, the fabrication of integrated circuits includes forming n-channel and p-channel Field-Effect Transistors (FETs). Each of the n-channel FET (n-FET) or p-channel FET (p-FET) comprises a channel region, a source region, and a drain region. The n-FET has source-and-drain (S/D) regions which are doped with an n-type dopant, e.g. phosphorus, arsenic, or both. The p-FET has S/D regions doped with a p-type impurity, e.g. boron or gallium, or the like. The channel regions, source regions, and drain regions may be formed through epitaxy, and are represented as semiconductor layer 12 as shown in FIGS. 2, 3, and 12. Furthermore, the semiconductor layer 12 may include silicon (Si) or Silicon-Germanium (Si₁₋ₓGeₓ) with various germanium concentration or mole fraction x. As an example, the n-FET's S/D regions may comprise a layer of arsenic-doped silicon (Si:As) underlying a layer of phosphorus-doped silicon (Si:P), formed by introducing a silicon-containing precursor and an arsenic-containing precursor (e.g. arsine, AsH₃) or a phosphorus-containing precursor (e.g. phosphine, PH₃), respectively. The p-FET's S/D region may comprise a boron-doped Si₁₋ₓGeₓ. The n-FET's S/D or p-FET's S/D may each be formed by using multiple steps of epitaxy and etching.

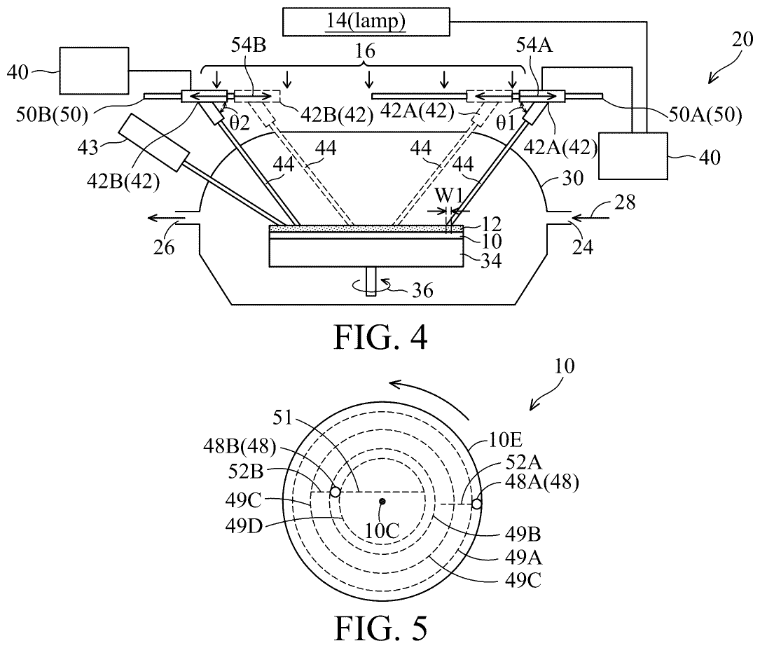

Referring to FIG. 4, production tool 20, which includes chamber 30 that is used for the epitaxial growth of semiconductor layer 12 as shown in FIGS. 2 and 3, is shown. Production tool 20 may be used to perform the deposition process such as CVD, RPCVD, ALD, PECVD, or the like. The wafer 10 is placed on susceptor 34, which may be an electro chuck in accordance with some embodiments. When depositing silicon, silicon germanium, or germanium as semiconductor layer 12, the pressure during the epitaxy process may range from about 1 Torr to about 800 Torr, and silicon-containing precursors (such as silane (SiH₄), disilane (Si₂H₆), etc.) and germanium-containing precursors (e.g. germane (GeH₄), digermane (Ge₂H₆), etc.) may be used. The corresponding wafer 10 is heated with a controlled wafer temperature during the epitaxial growth, which temperature may range from about 300° C. to about 900° C. To heat wafer 10 to the desirable temperature, a lamp-based heating source such as lamp 14 may be used as a main heating source, so that light/radiation 16 is provided to heat wafer 14. In accordance with some embodiments, lamp 14 comprises a halogen-based lamp, which may project light in the visible spectrum or broad spectrum light ranging from infra-red (IR) to ultra-violet (UV). The lamp may also comprise multiple zones, such as an outer zone and an inner zone with separate controls. In accordance with alternative embodiments, wafer 10 is heated from under, and the susceptor 34 may be heated to heat wafer 10. The heating of the susceptor may be performed using a bottom lamp-based heating, which can also comprise multiple zones. In accordance with alternative embodiments, both of lamp 14 and the heated susceptor 34 are adopted. In accordance with some embodiments, both top lamp-based heating and bottom lamp-based heating are used in combination.

Referring back to FIG. 2, epitaxial semiconductor layer 12 may have non-uniformity in the thickness when a wafer-level heating source such as lamp 14 and/or an under-wafer heating unit is used. For example, at the center of wafer 10 (FIG. 2), the thickness of semiconductor layer 12 is T1, while at the edge of wafer 10, the thickness of semiconductor layer 12 is T2, which may be smaller than thickness T1. Thickness T2 may also be the smallest among wafer 10. This may be caused due to the combination of heat loss by convection or radiation, which heat-loss is the highest at wafer edge and lower in middle portions of wafer 10. In the regions between the center and the edge of wafer 10, the thickness of semiconductor layer 12 may be smaller than thickness T1 and greater than thickness T2. Depending on the material, the epitaxy process, etc., there may be different types of non-uniformity. For example, FIG. 2 illustrates a scenario wherein from the center to the edge of wafer 10, semiconductor layer 12 has continuously reduced thicknesses. FIG. 3 illustrates a scenario, wherein in region 18, which is between the wafer center and the wafer edge, the thickness T3 of semiconductor layer 12 is smaller than both of thicknesses T1 and T2.

In accordance with alternative embodiments, instead of epitaxially growing semiconductor layer 12, an etching process is performed on semiconductor layer 12. This may be performed, for example, in order to adjust the thicknesses of the deposited semiconductor layer 12, removing the semiconductor material that is undesirably grown on dielectric regions, or the like. Similar to the epitaxy process, the etching of semiconductor layer 12 may also have the non-uniformity issue, with some parts undesirably etched more (or less) than other parts. The etching of semiconductor layer 12 may also be performed in the production tool 12 as in FIG. 4. In accordance with some embodiments, both of the epitaxy and the etching of semiconductor layer 12 may be performed using production tool 20, and may be in-situ performed, for example, without vacuum break between the epitaxy and the etching of semiconductor layer 12.

An example embodiment shown in FIG. 4 addresses the non-uniformity issue as shown in FIGS. 2 and 3. In FIG. 4, production tool 20 includes process chamber or vacuum chamber 30, which is configured to be operated at pressures below one atmospheric pressure for performing epitaxy and the etching of semiconductor layer 12.

Wafer 10 is placed on, and is secured on, susceptor (E-Chuck) 34. In accordance with some embodiments, susceptor 34 is configured to be rotated, as shown by arrow 36. Lamp 14 is provided, and is configured to project light 16 on wafer 10 in order to heat wafer 10. In accordance with some embodiments, lamp 14 projects visible light or light having broad spectrum ranging from infrared to UV. Lamp 14 may be located outside or inside chamber 30. Inlet 24 and outlet 26 are used to conduct process gases 28 into vacuum chamber 30, and evacuate precursors 28 out of chamber 30. Process gases 28, depending on the composition of the semiconductor layer 12 to be grown, may include silane (SiH₄), disilane (Si₂H₆), germane (GeH₄), digermane (Ge₂H₆), or the like. Process gases 28 may also include an etching gas such as HCl to achieve selective growth on semiconductor, but not on dielectric. In accordance with alternative embodiments, instead of performing epitaxial growth, an etching process is performed, wherein process gases 28 include an etching gas such as HCl, Cl₂, or any other halogen-containing gas.

At least a top part (which part may have a transparent window) of the chamber wall of chamber 30 is transparent for a laser beam, as will be discussed in detail in subsequent paragraphs. In accordance with some embodiments, the transparent chamber wall 30 is formed of or comprises quartz, silicon oxide, a ceramic, a glass, or the like.

One or a plurality of laser projectors 42 (including projectors 42A and 42B, for example) is provided. Laser projectors 42 are configured to generate laser beams 44, and projects laser beams 44 on wafer 10. Laser beams 44 penetrate through the transparent chamber wall or window to reach wafer 10, so that the temperature of the projected area of wafer 10 is increased. The laser beams 44 are directed onto the regions where the thickness or critical dimensions of the epitaxial layer are to be tuned differently from other regions. The laser beams 44 are also directed to wafer areas where temperatures are lower than in other wafer areas, so that the temperature uniformity is improved. The laser beams 44 have tilt angles θ1 and θ2 with respect to the horizontal plane, which is parallel to the top surface of wafer 10. Tilt angles θ1 and θ2 may be in the range between about 30 degrees and about 100 degrees, and may be in the range between about 45 degrees and about 90 degrees. Tilt angle θ1 and θ2 are controlled by actuators that are in turn controlled by controller 40. Each of the laser projectors 42 is mounted on a holder or a stage, which is further mounted on a track 50. The positions of the stages on the tracks 50 are also controlled by controller 40.

The wavelength of the laser beams 44 may be in the range between about 200 nm and about 1,200 nm, and may be in the range between about 600 nm and about 950 nm. The lateral dimension W1 of the laser beam spot may be in the range between about 2 mm and about 20 mm, and may be in the range between about 5 mm and about 15 mm. The spot size of laser beam 44 is related to the desirable temperature change caused by laser beam 44, and the intended temperature change rate (the temperature change in a unit time, ° C./minute). A smaller diameter enables a more precise and more selective heating in a more localized region, and a quicker temperature ramp-up. The spot size may be adjusted by adjusting the distance between laser projectors 42 and wafer 10, and by adjusting the focus.

Laser projectors 42 may be of various types, and the resulting laser beams 44 may be selected from a plurality of different types. For example, the resulting laser may be gas laser (e.g. helium-neon laser), excimer laser (such as KrF laser (with wavelength being about 248 nm)), XeCl laser (with wavelength being about 308 nm), or XeF laser (with wavelength being about 351 nm), solid-state laser, semiconductor diode laser, or other lasers. The laser power incident on the wafer 10 may be in the range between about 30 Watts and about 200 Watts, and may be in the range between about 50 Watts and about 150 Watts. The laser power may be fixed or may be tuneable. For example, for solid state lasers or semiconductor diode laser, the power may be tuned by adjusting the input driving current of laser projectors 42.

The laser affects the epitaxial growth process through several mechanisms. First, the laser is absorbed by the surface of wafer 10, generating excited carriers and phonons, leading to increased temperature in a localized region. The increased temperature results in a higher growth rate. Second, the laser interacts with the gaseous precursors in the region on the paths of the laser beams 44, altering the molecular and radical species. This may improve the efficiency of the generation of species and ions, and also leads to an increased growth rate.

FIG. 5 illustrates an example of a top view of wafer 10, which has center 10C and edge 10E, which edge 10E is circular. Wafer 10 is rotated with respect to center 10C during the epitaxial growth process. Laser beam spot 48 (marked as 48A) is illustrated, and is at the edge of wafer 10. Wafer 10 may be rotated at a speed in the range between about 1 round per minute and about 60 rounds per minute. With the rotation of wafer 10, the laser beam spot 48A is projected to at least the entire region between circle 49A and the edge 10E of wafer 10.

Referring back to FIG. 4, there may be a single laser projector 42 in accordance with some embodiments. In accordance with alternative embodiments, there are a plurality (two, three, or more) of laser projectors 42 operating independently. The lasers may not be identical, and may have different wavelengths, spot sizes, power rating, etc. For example, FIG. 4 illustrates laser projector 42B, which also generates a laser beam 44 and projects the corresponding laser beam 44 on wafer 10 during the epitaxy process.

In accordance with some embodiments, at least one, more, or all of laser projectors 42 are attached to the corresponding tracks 50, so that corresponding laser projectors 42 may slide during the epitaxy process. FIG. 4 illustrates arrow 54A representing the back-and-forth movement of laser projector 42A, and a dashed laser projector 42A representing laser projector 42A is at another position when it slides. Arrow 54B represents the back-and-forth movement of laser projector 42B, and a dashed laser projector 42B representing that laser projector 42B is at another position when it slides. With the sliding of laser projectors 42 on tracks 50, the corresponding laser beam spot move on wafer 10, which may be in any range between the center and the edge of wafer 10. For example, referring to FIG. 5, laser beam spot 48A may move along dashed line 52A (which is a locus of laser beam spot 48A) back-and-forth while wafer 10 is rotated at the same time. Laser beam spot 48B may move along dashed line 52B (which is a locus of laser beam spot 48B) back-and-forth while wafer 10 is rotated at the same time. Accordingly, the entire region between dashed circle 49C and dashed circle 49D is impacted by the corresponding laser beam 44.

In accordance with some embodiments, the laser projector 42A (and possibly other laser projectors) moves continuously during the epitaxial growth. The laser beam 44 can scan back-and-forth between, or aim at, two positions, namely position 1 and position 2. The speed or frequency of the scan can range from about 0.1 cycles per minute to about 60 cycles per minute. The continuous scan can either be achieved by altering the angle of the laser beam or moving the stage along the corresponding track 50, or both. This allows the region of influence of the laser beam 44 to be significantly extended.

Laser projector 42B (FIG. 4) may be operated independent from the operation of laser projector 42A. For example, laser projector 42B may be fixed, or may slide along the respective track 50B during the epitaxy process. In accordance with some embodiments, the projected wafer area on wafer 10 by laser projector 42A overlaps, partially or fully, with the projected wafer area on wafer 10 by laser projector 42B. In accordance with alternative embodiments, the laser beams 44 of laser projector 42A and laser projector 42B impact different and non-overlapping wafer areas. For example, the laser beam 44 of laser projector 42A may be projected on a wafer area closer to the wafer edge 10E, while the laser beam 44 of laser projector 42B may be projected on a wafer area closer to the wafer center 10C.

As shown in FIG. 5, the locus (the movement track) of a laser beam spot 48 may be aligned along a diameter of wafer 10, or may be misaligned from any diameter of wafer 10. For example, the locus of laser beam spot 48A is aligned with a diameter of wafer 10, while the locus of laser beam spot 48B is misaligned from diameters of wafer 10, and the extension line 51 of the locus of laser beam spot 48B does not pass through wafer center 10C. The alignment/misalignment of laser beam tracks from the diameters affect the energy received by wafer 10, and the wafer temperature of the affected wafer area. For example, assuming the locus of laser beam spots 48A and 48B have the same lengths, laser beam spot 48B, being on a diameter, may cover more wafer area than laser beam spot 48B, which is not aligned to any diameter.

Referring back to FIG. 4 again, the tilt angles θ1 and θ2 of at least one, more (in any combination), or all of laser projectors 42 may be adjusted during the epitaxy process. The adjustment of tilt angles θ1 and θ2 also results in the locations of the laser beam spot to be moved in wafer area. For example, when projecting angles θ1 and θ2 are varied during the epitaxy process, laser beam spots 48A and 48B (FIG. 5) may also be moved back-and-forth along locus 52A and 52B, respectively. In addition, the change of projecting angles θ1 and θ2 and the movement of laser projectors 42 on tracks 50 may be performed simultaneously to result in a more tuned and non-linear movement of laser spots, so that the temperature of wafer 10 may be more fine-tuned. Furthermore, when laser projectors 42 slide on their respective tracks 50, their sliding speed may be a constant, or may change when the spot of the laser beam 44 lands on different areas of wafer 10. When the laser beam spot passes through the wafer areas that need more thickness compensation, the sliding speed may be reduced. Conversely, when the laser beam spot passes through the wafer areas that need smaller thickness compensation, the sliding speed may be increased. Similarly, the change of the moving speed of laser beam(s) 44 to be non-constant may be achieved by the tilting of laser projectors 42.

In accordance with some embodiments, one or more pyrometers 43 is used to measure the temperature at specific locations on wafer 10. Pyrometers 43 may be placed outside chamber 30. A pyrometer 43 may be used to measure the temperature of the region where the laser beam is directed, and the detected temperature can be fed back to a computer system which adjusts the power, intensity, moving speed, moving range, etc. of the laser beam 44 to ensure that the temperature is controlled in a stable manner within a specification.

In accordance with some embodiments, a laser beam spot 48 is not moved and the wafer 10 rotates. In this case, as far as the entire wafer 10 is concerned, the laser beam spot 48 makes an impact on a circular ring region of wafer 10. For example, if the rotation speed of wafer 10 is about 60 rounds per minute or about 1 round per second, a specific location on the wafer in this circular ring region will experience a laser pulse every second. The frequency of the laser pulse is higher if the rotation speed is increased. During the projection of laser beam(s) 44, the temperature of the impacted wafer region rises when a location on the wafer 10 is pulsed with the laser radiation, causing the local temperature to increase and the local growth rate to increase during the epitaxy process. The pyrometer 43 thus measures the temperature of the same ring region as the laser beam 44 is projected. The pyrometer 43 may or may not measure the same spot where laser beam 44 is projected, as long as pyrometer 43 measures the same ring region laser beam 44 is projected.

The power or intensity of the laser beams 44 can be kept constant during the growth of the semiconductor layer or can be dynamically altered over time. For example, the laser power can be about 80 Watts for 20 seconds, followed by about 50 Watts for 30 seconds. The adjusting of the power of the laser beam may also be combined with the movement and the adjustment of the projection angles of laser projector 42 to achieve more fine-tuned adjustment of power. For example, when the laser beam spot passes through the wafer areas that need more thickness compensation, the laser power may be increased. Conversely, when the laser beam spot passes through the wafer areas that need smaller thickness compensation, the laser power may be reduced. When the laser beam spot passes through the wafer areas that do not need thickness compensation, the laser power may be turned off. Furthermore, when the laser projector 42 travels on its track 50 in one direction, the laser beam 44 may be turned on and off for multiple cycles, and the power may also be adjusted for multiple cycles, to achieve different heating to multiple ring-zones on wafer 10.

Production tool 20 includes controller 40, which is electrically and signally connected to the various units of production tool 20. For example, controller 40 is configured to control and synchronize the turning on and turning off of lamp 14, the turning on and turning off of laser projectors 42, the movement of laser projectors 42 (including the traveling speed, the traveling range, the power of laser beam, etc.), the tilting angles θ1 and θ2 of laser projectors 42, and the like.

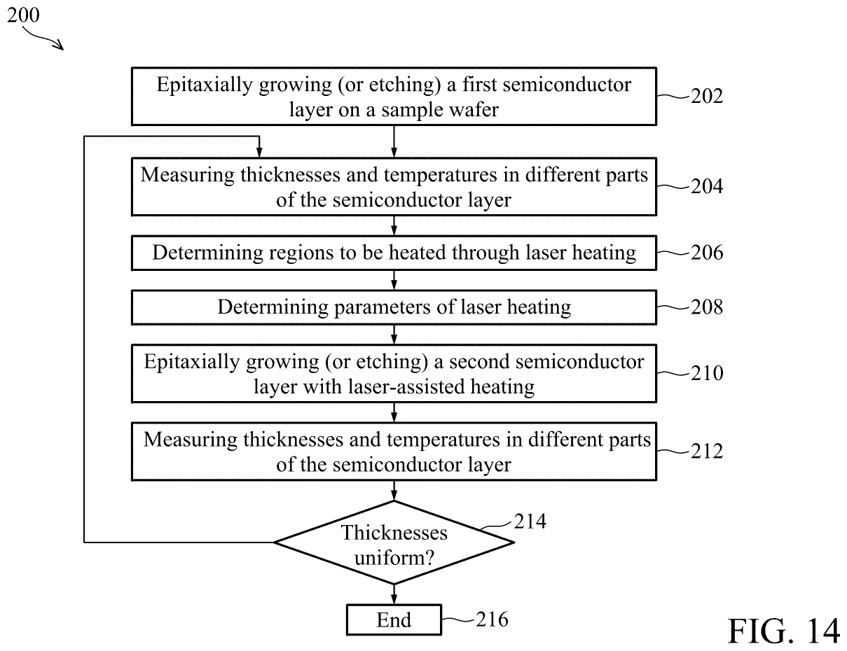

FIG. 14 illustrates an example process flow 200 for determining the process parameters of laser-assisted epitaxy in accordance with some embodiments. First, a first sample semiconductor layer is epitaxially grown on a first sample wafer. The first sample wafer and the first sample semiconductor layer may be represented by wafer 10 and semiconductor layer 12 in FIG. 2 or FIG. 3. Furthermore, the first semiconductor layer may be a blanket layer grown throughout the sample wafer. The corresponding process is illustrated as process 202 in the process shown in FIG. 14. The first sample semiconductor layer is epitaxially grown without the laser-assisted heating. For example, lamp 14 (FIG. 4) may be used for the heating of the wafer. The temperatures at different part of the wafer may also be measured, for example, using pyrometers. The temperature throughout the wafer may not be uniform. The first semiconductor layer may have non-uniform thicknesses at different parts of the first sample wafer. The thicknesses at different parts of the wafer are also measured. The corresponding process is illustrated as process 204 in the process shown in FIG. 14. The difference in the thicknesses is determined, and the locations of the wafers that should adopt laser-assisted heating are determined. The corresponding process is illustrated as process 206 in the process shown in FIG. 14. The parameters of the laser beams to achieve the temperature and thickness compensation are determined. The corresponding process is illustrated as process 208 in the process shown in FIG. 14. For example, the parameters of the laser beams may include, and are not limited to, the number of laser beams (and laser projectors), the power of the laser beam, the traveling range and speed of the laser projector on the tracks, the tilting angle and the corresponding durations, etc..

With the parameters of the laser beams determined, a second sample semiconductor layer is epitaxially grown on a second sample wafer, and the corresponding epitaxial growth is performed using the previously determined parameters of the laser beams. The corresponding process is illustrated as process 210 in the process shown in FIG. 14. With the laser-assisted heating, the temperature uniformity throughout the second sample wafer is improved over the first sample wafer. The thicknesses of the second semiconductor layer are then measured. The corresponding process is illustrated as process 212 in the process shown in FIG. 14. If the thicknesses of the second semiconductor layer are uniform enough (determined by process 214) to fall within the specification, the process is ended (process 216), and the corresponding parameters of the laser beams are used for the production of semiconductor wafers. If, however, the thicknesses of the second semiconductor layer are not uniform, the process loops back to process 204 to fine tune the parameters of the laser beams, until the thicknesses of the resulting semiconductor layer falls within specification.

It is appreciated that the process flow 200 may also be used for the etching of semiconductor layers, as will be discussed in subsequent paragraphs. The processes for determining parameters for laser-assisted etching are similar to the epitaxy of semiconductor layers, except that instead of epitaxially growing semiconductor layers, the grown semiconductor layers are etched.

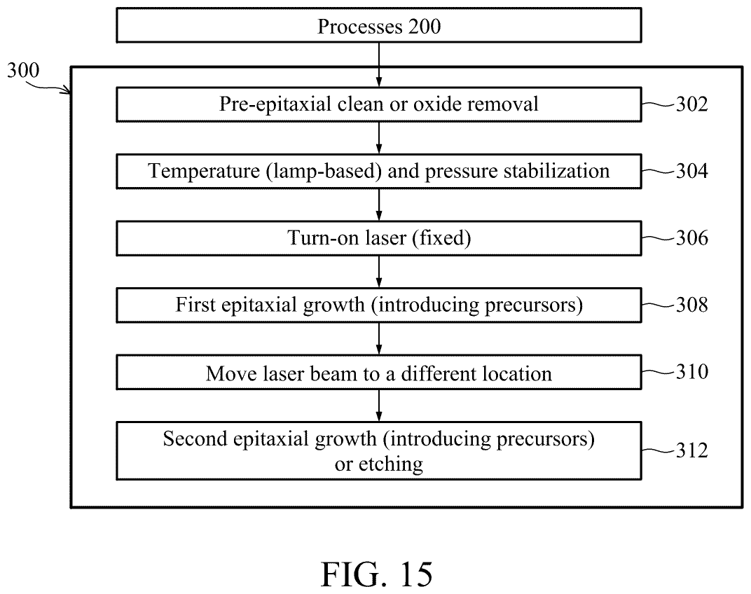

FIG. 15 illustrates a process flow 300 for epitaxially growing a semiconductor layer through laser-assisted heating. The processes in process flow 300 may be performed in production tool 20 as shown in FIG. 4. In accordance with some embodiments, the parameters for the laser beams have been determined, which may be through the process flow 200 as shown in FIG. 14. Next, as shown in process 302, a pre-epitaxial clean process is preformed, which may include an oxide removal process. The pre-epitaxial clean process may include an etching process using the mixture of NH₃ and HF, an etching process using HF vapor, or a thermal treatment or anneal process using H₂. Next, in process 304, the temperature of wafer 10 (FIG. 4) is ramped up to the desired growth temperature (for example, about 300° C. to about 900° C.) using the lamp-based heating. The pressure in chamber 30 is also set at the desirable pressure for the epitaxial growth (for example, in the range between about 1 Torr and about 800 Torr). At this point, the temperature on the surface of the wafer may not be as uniform as desired (and can be measured), and the laser is then turned on to provide additional heating to the locations where the laser-assisted heating is needed, as shown in process 306. The locations receiving the laser-assisted heating may be near the wafer edge, but may also be at other desired locations such as the wafer center, or any other area between the wafer center and the wafer edge. The temperatures at different locations may be measured using pyrometers. With the temperature profile modified to the desirable temperatures, the precursors are then introduced to initiate the epitaxial growth (process 308). A carrier gas such as H₂ or N₂ may be introduced along with precursor gases such as silicon-containing gases (e.g. silane SiH₄, disilane Si₂H₆, etc.) and/or germanium-containing precursors (e.g. germane GeH₄, digermane Ge₂H₆, etc.), as well as dopant gases (e.g. B₂H₆, PH₃, AsH₃, etc.).

Further referring to FIG. 15, the epitaxy process may be a single-step epitaxy process or a multi-step epitaxy process. In this case, the laser beam spot is positioned at a first location during a first epitaxial growth. Once the first epitaxy growth is ended, the laser beam spot may be moved to a second location on wafer 10, wherein the second location is different from the first location. The moving of the laser beam spot may either be through altering the projecting angle of the laser beams 44 (FIG. 4), moving the stage along the track 50, or both. A second epitaxial growth is then performed with the laser beams 44 projected to the second location. The first epitaxial growth and the second epitaxial growth may be the growth of the same semiconductor material, or may be for growing different semiconductor materials.

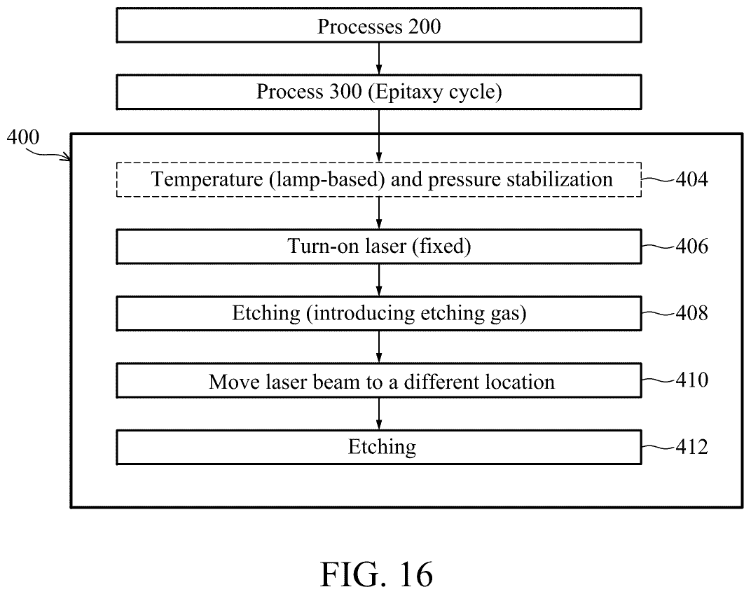

FIG. 16 illustrates an example process flow 400 of an etching process, which may be performed after epitaxy processes. For example, in FIG. 16, processes 200 (FIG. 14) are performed to determine process parameters for the laser-assisted heating during etching processes. Next, an epitaxy process 300 may be performed. The details of process 300 are shown in FIG. 15. Process 404 illustrates the ramping up and the stabilization of wafer temperature, and the pressure stabilization, if the temperature is different from the temperature set during epitaxy process 300. The details may be similar to process 304 in FIG. 14. At this point, the temperature on the surface of the wafer may not be as uniform as desired, and the laser is then turned on to provide additional heating to the locations where the laser-assisted heating is needed, as shown in process 406. With the temperature profile modified to the desirable temperatures, the etching gas is then introduced to initiate the etching process (process 408). The laser beams may then be moved to another location(s), if needed, and further etching may be performed, as shown in processes 410 and 412.

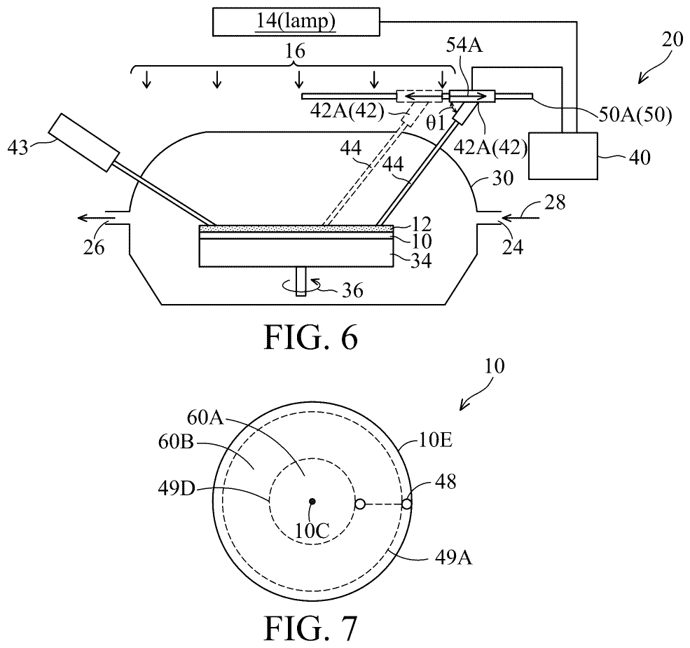

FIGS. 6 through 11 illustrate the production tool 20 and the corresponding top views of wafer 10 in accordance with some embodiments. These embodiments are similar to the embodiments shown in FIGS. 4 and 5, except that in FIGS. 6 through 11, fewer components are adopted to achieve the laser-assisted heating. Accordingly, the discussion of the embodiments as shown in FIGS. 6 through 11 also applies to the embodiments as shown in FIGS. 4 and 5, and vice versa.

FIGS. 6 and 7 illustrate that production tool 20 has a single laser projector 42A, which may travel along track 50A, with the back-and-forth movement represented by arrow 54A. Also, the projecting angle θ1 may be adjusted. Furthermore, during the traveling of laser projector 42A on track 50A, the laser beam 44 may be turned on-and-off at selected regions, so that the selected regions of wafer 10 may receive the laser beam. FIG. 7 shows a top view of wafer 10 as in FIG. 6. The region 60B, which is between dashed circle 49A and dashed circle 49D, may receive the laser beam 44, which is achieved by turning laser beam on when the laser beam travels into these regions. The center region 60A (inside dashed circle 49D) does not receive the laser beam 44. This may be achieved by turning laser beam 44 off when the laser beam travels into this region, or by not making the laser beam traveling into this region. It is appreciated that since the laser projector 42A may slide back-and-forth multiple times, the turning on-and-off (if laser beam 44 travels out of region 60B) may be performed multiple time when the corresponding laser beam 44 enters and exists the selected regions.

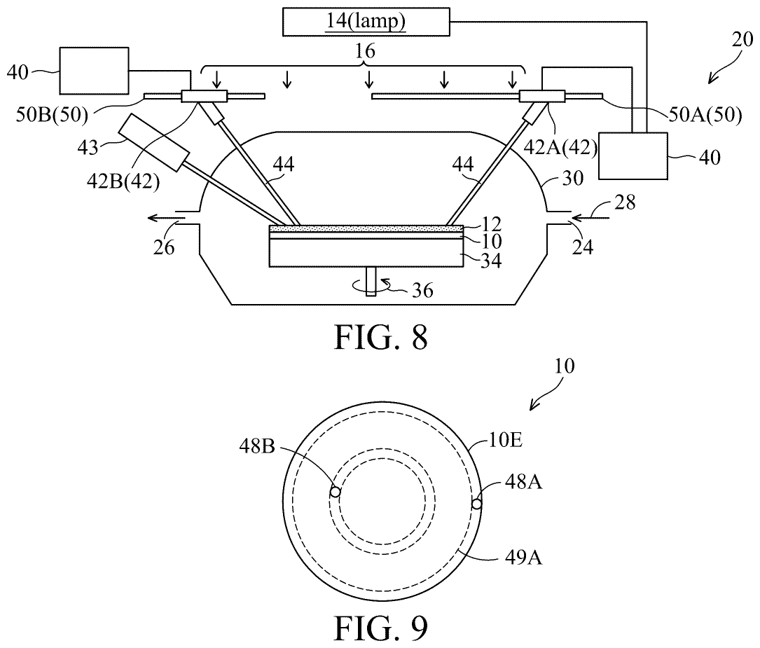

FIG. 8 illustrates an embodiment in which two laser projectors 42A and 42B are used. Each of the two laser projectors 42A and 42B may have its laser beam 44 fixed in position on wafer 10, or may have its laser beam 44 movable, either through having the corresponding projectors 42A and 42B moving on the respective tracks, or through adjusting the projecting angles of laser beams 44. The respective top view of wafer and the laser beam spots 48A and 48B are shown in the top view as in FIG. 9.

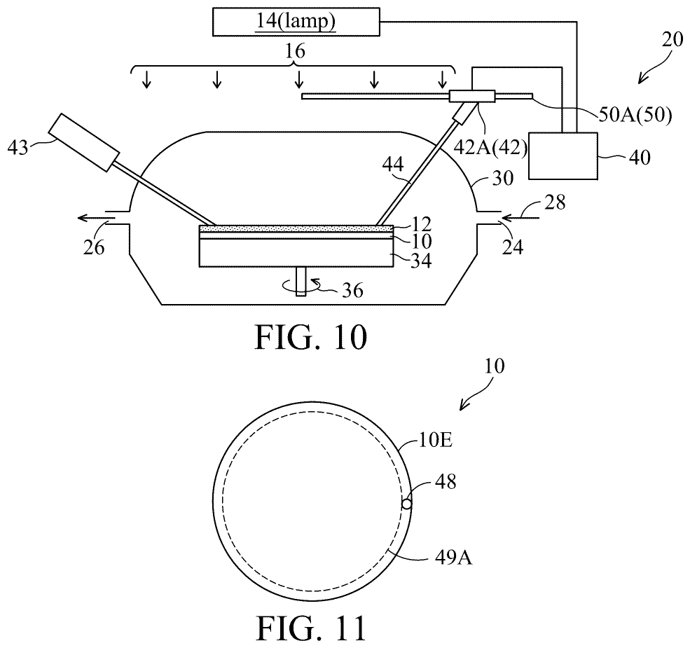

FIG. 10 illustrates an embodiment in which a single laser projector 42 is used, and the corresponding laser beam spot 48 (the top view as in FIG. 11) is fixed, and hence the laser-assisted heating is provided to a ring-shaped region between dashed circle 49A and wafer edge 10E.

As addressed in the discussion of FIGS. 1 through 3, the deposited semiconductor layer may be a continuous (blanket) film covering the entire wafer surface, or may include discrete regions that are not continuous. For example, in some epitaxy processes, the growth occurs in certain selected regions. FIG. 12 illustrates the epitaxial growth of source/drain (S/D) regions 12, which are grown on top of the semiconductor regions 64. All other regions such as fin spacers 68, gate spacers (not shown), Shallow Trench Isolation (STI) regions 66, or the like, do not incur epitaxial growth. Source/drain regions 12 may be arsenic-doped silicon (Si: As) or phosphorus-doped silicon (Si:P) for n-FETs, and may be boron-doped silicon-germanium (Si₁₋ₓGeₓ:B) for p-FET, wherein Si₁₋ₓGeₓ:B may have various germanium mole fraction x.

In this example, the critical dimensions (CDs) of the S/D regions 12 (rather than the thicknesses measured in vertical directions) need to be uniformly controlled. For example, the CD or width of the S/D regions 12 at a first location (for example, the center) of the wafer 10 may be CD1. Width CD1 may be an averaged width obtained by measuring a plurality of S/D regions 12 in a die at or near the first location. At a second location away from the first location, e.g. with distance S1 from the first location, the average CD or width of the S/D regions 12 may be CD2. CD2 may be different from CD1. Assuming that without the use of laser-assisted heating, CD2 is smaller than CD1. A laser beam 44 may then be used to cover the wafer region at the second location to increase the local CD of S/D regions 12. Accordingly, through laser-assisted heating, a more uniform lateral dimension for S/D regions 12 is achieved across the wafer.

The amount of increase in the lateral dimension of a selected region on the wafer can be adjusted by varying the power of the laser beam. As mentioned previously, as an example, the laser power that is projected on the wafer 10 may be in the range between about 30 Watts and about 200 Watts, and may be in the range between about 50 watts and about 150 Watts. A higher power leads to a higher local growth rate, and vice versa. During the operation of the laser beam 44, the power can be fixed as a constant during the growth step, or it can be varied over time.

In the S/D epitaxial growth, etching gases such as chlorine-containing precursors (e.g. Cl₂, HCl) may be used. Gases such as HCl may be introduced during epitaxial growth to remove unwanted nucleation of semiconductor growths on dielectric surfaces (or nodules). In addition, the epitaxial growth may be followed by an etch process. For example, a process sequence may involve epitaxy, etching, and epitaxy. The etching process can be used to remove nodules or to tune the CDs or shapes of the S/D regions 12. In accordance with some embodiments, an etching temperature (of wafer 10) may be in the range between about 300° C. and about 900° C., and may be in the range between about 500° C. and about 800° C., or between about 550° C. and about 750° C.

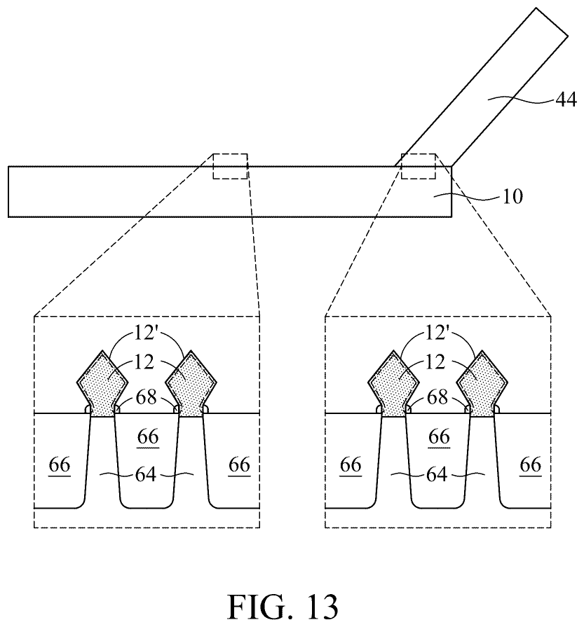

FIG. 13 illustrates an example of an etching process, during which wafer 10 may also be in chamber 30 (FIG. 4), and an etching gas is conducted in chamber 30 also. Through the etching, the surfaces of source/drain regions 12 are reduced to where dashed lines 12′ are. The laser beam 44 may be directed onto a region near the wafer edge (or any other wafer area in which a higher etching rate is desirable), where more etching is to be done, with respect to the wafer center. The etching by Cl-containing species is also thermally activated, and a higher etch rate is observed where the temperate of the corresponding part of wafer 10 is higher. By directing the laser beam spot at a localized region, the local wafer temperature is increased, and the etching rate is increased. In an example embodiment, the etching rate at wafer edge is smaller than at wafer center when no laser-assisted heating is provided. Accordingly, laser-assisted heating is provided to wafer edge, but not to wafer center. Conversely, if more etching is to be achieved at the wafer center than the wafer edge, the laser beam will be directed to the wafer center during the etch process.

The embodiments of the present disclosure have some advantageous features. By performing laser-assisted epitaxy and etching processes, the uniformity of the wafer temperature is improved, and whole-wafer uniformity in the epitaxy and etching processes may be achieved.

In accordance with some embodiments of the present disclosure, a method includes placing a wafer into a production chamber; providing a heating source to heat the wafer; projecting a first laser beam on the wafer using a first laser projector; and with the wafer being heated by both of the heating source and the first laser beam, performing a process selected from an epitaxy process to grow a semiconductor layer on the wafer, and an etching process to etch the semiconductor layer. In an embodiment, during the process, the first laser projector slides on a track, so that the first laser beam moves on the wafer. In an embodiment, during the process, a projecting angle of the first laser beam on the wafer is changed by changing a tilting angle of the first laser projector. In an embodiment, the method further comprises, during the process, further projecting a second laser beam on the wafer using a second laser projector. In an embodiment, the method further comprises, during the process, adjusting a power of the first laser beam. In an embodiment, the method further comprises, during the process, turning off the first laser beam when the first laser beam enters into a first area of the wafer; and turning on the first laser beam when the first laser beam enters into a second area of the wafer. In an embodiment, the method further comprises performing the turning off and the turning on a plurality of cycles corresponding to the first laser beam entering the first area and the second area of the wafer for a plurality of times. In an embodiment, the process comprises the epitaxy process to grow the semiconductor layer on the wafer. In an embodiment, the process comprises the etching process to etch the semiconductor layer.

In accordance with some embodiments of the present disclosure, a method includes heating a wafer using a lamp-based heating source; rotating the wafer; performing an epitaxy process to grow a semiconductor layer on the wafer; during the epitaxy process, performing a laser-assisted heating process on selected regions of the wafer, wherein the laser-assisted heating process comprises projecting a first laser beam on a first area of the wafer, wherein the first laser beam is kept outside of a second area of the wafer; performing an etching process to etch back the semiconductor layer; and during the etching process, performing a laser-assisted heating process, wherein the laser-assisted heating process comprises projecting the first laser beam on a third area of the wafer, wherein the first laser beam is kept outside of a fourth area of the wafer. In an embodiment, the method further comprises epitaxially growing a first sample semiconductor layer on a first sample wafer; measuring temperatures of different parts of the first sample wafer during the epitaxially growing the first sample semiconductor layer; measuring thicknesses of the different parts of the first sample semiconductor layer; and determining laser-assisted heating parameters based on the measured temperatures and the measured thicknesses. In an embodiment, the method further comprises epitaxially growing a second sample semiconductor layer on a second sample wafer using the determined laser-assisted heating parameters; measuring temperatures of different parts of the second sample wafer during the epitaxially growing the second sample semiconductor layer; measuring thicknesses of the different parts of the second sample semiconductor layer; and tuning the laser-assisted heating parameters based on the measured temperatures and the measured thicknesses from the second sample semiconductor layer and the second sample wafer. In an embodiment, during the epitaxy process, the first laser beam moves on the wafer. In an embodiment, the laser-assisted heating process further comprises projecting a second laser beam on a part of the wafer. In an embodiment, during the epitaxy process, a power of the first laser beam is changed to have different values.

In accordance with some embodiments of the present disclosure, an apparatus configured to perform an epitaxy process on a wafer, the apparatus comprises a process or vacuum chamber, wherein the process or vacuum chamber comprises at least an inlet and at least an outlet; a susceptor configured to hold the wafer thereon, wherein the susceptor is configured to rotate the wafer; a lamp configured to heat the wafer; and a first laser projector configured to project a first laser beam on the wafer. In an embodiment, the first laser projector is configured to slide on a track to move a laser beam spot of the first laser beam. In an embodiment, the apparatus further comprises a second laser projector configured to project a second laser beam on the wafer. In an embodiment, the apparatus further comprises a controller configured to control the lamp and the first laser projector. In an embodiment, the first laser projector is located outside of the vacuum chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
placing a wafer into a process chamber;
heating the wafer using a heating source;
rotating the wafer;
with the wafer being rotated, projecting a first laser beam on selected regions of the wafer using a first laser projector, wherein the first laser beam moves on the wafer back-and-forth along a path, and wherein a first region heated by the first laser beam has an inner boundary forming a first circle, and an outer boundary forming a second circle, and wherein a second region encircled by the first circle is outside of regions heated by the first laser beam; and
when the wafer is heated by the first laser beam, performing a deposition process to deposit a layer over the wafer.

2. The method of claim 1 further comprising:
projecting a second laser beam on the wafer to perform an etching process, wherein during the etching process, the second laser beam is projected on a third region of the wafer, and wherein the second laser beam is kept outside of a fourth region of the wafer.

3. The method of claim 1, wherein:
when the first laser beam enters a first part of the wafer in the first region, the first laser beam is moved with a first moving speed; and
when the first laser beam enters a second part of the wafer in the first region, the first laser beam is moved with a second moving speed different from the first moving speed.

4. The method of claim 1, wherein the wafer further comprises a third region outside of, and encircling, the first region.

5. The method of claim 1, wherein in a top view of the wafer, the path is aligned to a straight line that passes through a center of the wafer.

6. The method of claim 1, wherein in a top view of the wafer, the path is aligned to a straight line that is misaligned from a center of the wafer.

7. The method of claim 1 further comprising adjusting a power of the first laser beam.

8. The method of claim 1 further comprising:
turning off the first laser beam when the first laser beam enters into a first area of the wafer in the first region; and
turning on the first laser beam when the first laser beam enters into a second area of the wafer in the first region.

9. The method of claim 1, wherein the first laser beam is projected by a laser projector, and the laser projector is configured to move on a guide, and is configured to tilt angle.

10. A method comprising:
heating a wafer using a lamp-based heating source, wherein the wafer comprises a center and a radius;
rotating the wafer;
performing an epitaxy process to grow a semiconductor layer on the wafer; and
during the epitaxy process, performing a laser-assisted heating process on selected regions of the wafer, wherein the laser-assisted heating process comprises projecting a first laser beam on a first area of the wafer back-and-forth along a first path, and wherein the first path has a length smaller than the radius.

11. The method of claim 10, wherein the first path is spaced apart from the center of the wafer.

12. The method of claim 10, wherein the first path is spaced apart from an outer edge of the wafer.

13. The method of claim 10, wherein the first laser beam is kept outside of a second area of the wafer.

14. The method of claim 13 further comprising:
performing an etching process to etch back the semiconductor layer; and
during the etching process, performing an additional laser-assisted heating process, wherein the additional laser-assisted heating process comprises projecting the first laser beam on a third area of the wafer, and wherein the first laser beam is kept outside of a fourth area of the wafer.

15. The method of claim 10, wherein the laser-assisted heating process further comprises projecting a second laser beam on a part of the wafer, wherein the second laser beam is moved along a second path different from the first path.

16. The method of claim 10, wherein during the epitaxy process, a power of the first laser beam is changed to different values.

17. A method comprising:
rotating a wafer;
performing an epitaxy process to grow a semiconductor layer on the wafer; and
during the epitaxy process, performing a laser-assisted heating process on selected regions of the wafer, wherein the laser-assisted heating process comprises projecting a laser beam on a first region of the wafer, wherein the first region has a ring-shape in a top view of the wafer, wherein the first region encircles a second region of the wafer, and wherein the laser beam is kept outside of the second region of the wafer.

18. The method of claim 17, wherein the wafer further comprises a third region encircling the first region, and wherein the laser beam is kept outside of the third region of the wafer.

19. The method of claim 17, wherein the laser beam travels back-and-forth on the wafer along a path.

20. The method of claim 17 further comprising:
projecting an additional laser beam on the wafer, wherein the laser beam and the additional laser beam are operated separately.
